(19) United States
(12) Patent Application Publication
(10) Pub. No.: US 2026/0160340 A1
(43) Pub. Date: Jun. 11, 2026

(54) ISOLATION VALVE

(71) Applicant: Lam Research Corporation, Fremont, CA (US)

(72) Inventors: Aaron Blake Miller, West Linn, OR (US); Panya Wongsenakhum, Fremont, CA (US)

(21) Appl. No.: 18/877,152

(22) PCT Filed: May 31, 2023
(86) PCT No.: PCT/US2023/023982

§ 371 Date: Dec. 19, 2024

Related U.S. Application Data
(60) Provisional application No. 63/388,079, filed on Jul. 11, 2022.

(51) Int. Cl. F16K 1/36; F16K 25/00; H10P 72/00

(52) U.S. Cl. CPC F16K 1/36; F16K 25/005; H10P 72/0402

(57) ABSTRACT

In some examples, an isolation valve is provided to isolate gasses and plasmas in semiconductor manufacturing. An example isolation valve comprises a valve body, a valve actuator, and a poppet comprising a polytetrafluoroethylene (PTFE) material, the poppet movable in the valve body by the valve actuator to hold the PTFE material in sealing engagement with an opposing surface without intervention of an O-ring.

### CLAIM OF PRIORITY

This application claims the benefit of priority to U.S. Provisional Patent Application Ser. No. 63/388,079, filed on Jul. 11, 2022, which is incorporated by reference herein in its entirety.

### TECHNICAL FIELD

The subject matter disclosed herein generally relates to an isolation valve for use in semiconductor manufacturing, and in some examples to components for an isolation valve.

### BACKGROUND

Semiconductor substrate processing systems are used to process semiconductor substrates by techniques comprising etching, physical vapor deposition (PVD), atomic layer deposition (ALD), chemical vapor deposition (CVD), plasma-enhanced chemical vapor deposition (PECVD), pulsed deposition layer (PDL), plasma-enhanced pulsed deposition layer (PEPDL), and resist removal. One type of semiconductor substrate processing apparatus is a plasma processing apparatus that comprises a vacuum process chamber containing upper and lower electrodes. In a substrate processing cycle, a radio frequency (RF) power is applied between the electrodes to excite a process gas into plasma for processing semiconductor substrates in the chamber.

The vacuum process chamber is typically supplied by process gas supply lines. The process supply lines may include one or more isolation valves that operate to isolate process gasses from cleaning gasses, as needed. Conventional isolation valves include O-ring sealing arrangements. High temperatures, aggressive dynamic response requirements, and hostile chemical environments can make valve applications particularly challenging in semiconductor processing. Isolation valves having conventional O-ring sealing arrangements fail quickly and often.

The background description provided herein is to generally present the context of the disclosure. It should be noted that the information described in this section is presented to provide the skilled artisan some context for the following disclosed subject matter and should not be considered as admitted prior art. More specifically, work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods and systems are presented for isolating gasses, such as process and cleaning gasses in semiconductor manufacturing. Some examples include an isolation valve and components for an isolation valve for use in semiconductor manufacturing.

In some examples, an isolation valve comprises a valve body; a valve actuator; and a poppet comprising a polytetrafluoroethylene (PTFE) material, the poppet movable in the valve body by the valve actuator to hold the PTFE material in sealing engagement with an opposing surface without intervention of an O-ring.

In some examples, the poppet is a unitary structure comprised entirely of or constructed entirely from the PTFE material.

In some examples, the poppet is devoid of an O-ring seating channel.

In some examples, the poppet comprises a recess or step.

Some examples further comprise a poppet valve assembly comprising a poppet valve housing and a section defined by the poppet.

In some examples, the poppet is formed separately to the poppet valve housing.

In some examples, the poppet valve assembly is a unitary structure with the section defined by the poppet formed integrally with the poppet valve housing.

In some examples, the poppet comprises a recess or step configured to fit with a matching formation inside the poppet valve housing.

In some examples, an O-ring-less poppet for an isolation valve is provided, the isolation valve comprising a valve body and a valve actuator, the O-ring-less poppet comprising: a section of (PTFE) material defining a sealing surface, the sealing surface devoid of an O-ring seating channel, the poppet movable in the valve body by the valve actuator to hold the sealing surface defined by the PTFE material in sealing engagement with an opposing surface without intervention of an O-ring when the isolation valve is closed.

In some examples, the O-ring-less poppet comprises a recess or step.

In some examples, the O-ring-less poppet is a unitary structure comprised entirely of or constructed entirely from the PTFE material.

In some examples, the isolation valve comprises a poppet valve assembly comprising a poppet valve housing and the O-ring-less poppet.

In some examples, the O-ring-less poppet is formed separately to the poppet valve housing.

In some examples, the poppet valve assembly is a unitary structure with the O-ring-less poppet formed integrally with the poppet valve housing.

In some examples, the O-ring-less poppet comprises a recess or step configured to fit with a matching formation inside the poppet valve housing.

In some examples, a poppet valve assembly for an isolation valve comprises a valve body and a valve actuator, the poppet valve assembly comprising: a poppet valve housing; and a poppet, the poppet comprising a section of (PTFE) material defining a sealing surface, the sealing surface devoid of an O-ring seating channel, the poppet movable in the valve body by the valve actuator to hold the sealing surface defined by the PTFE material in sealing engagement with an opposing surface without intervention of an O-ring when the isolation valve is closed.

In some examples, the poppet comprises a recess or step.

In some examples, the recess or step is configured to fit with a matching formation inside the poppet valve housing.

In some examples, the poppet is a unitary structure comprised entirely of or constructed entirely from the PTFE material.

In some examples, the poppet is formed separately to the poppet valve housing.

In some examples, the poppet valve assembly is a unitary structure with the poppet formed integrally with the poppet valve housing.

### BRIEF DESCRIPTION OF THE DRAWINGS

Various views of the appended drawings merely illustrate example embodiments of the present disclosure and should not be considered as limiting its scope.

FIG. 1 illustrates a process chamber, such as a deposition chamber, for manufacturing substrates, according to some example embodiments.

FIG. 2 is a schematic cross section of an isolation valve, according to an example embodiment.

FIGS. 3A-3C include isometric and side pictorial views of example poppets, according to example embodiments.

FIG. 4 is a block diagram illustrating an example of a machine upon which one or more example methods may be implemented, or by which one or more example embodiments may be controlled.

### DETAILED DESCRIPTION

Methods and systems are presented for isolating gasses, such as process and cleaning gasses and plasmas in semiconductor manufacturing. Example gasses and plasmas may include nitrogen trifluoride gas (NF3), hydrogen chloride gas (HCl), hydrogen fluoride gas (HF), fluorine-containing plasmas, and oxygen-containing plasmas. Some examples include an isolation valve and components for an isolation valve for use in semiconductor manufacturing. In the following description, for purposes of explanation, numerous specific details are set forth to provide a thorough understanding of example embodiments. It will be evident to one skilled in the art, however, that the present subject matter may be practiced without these specific details.

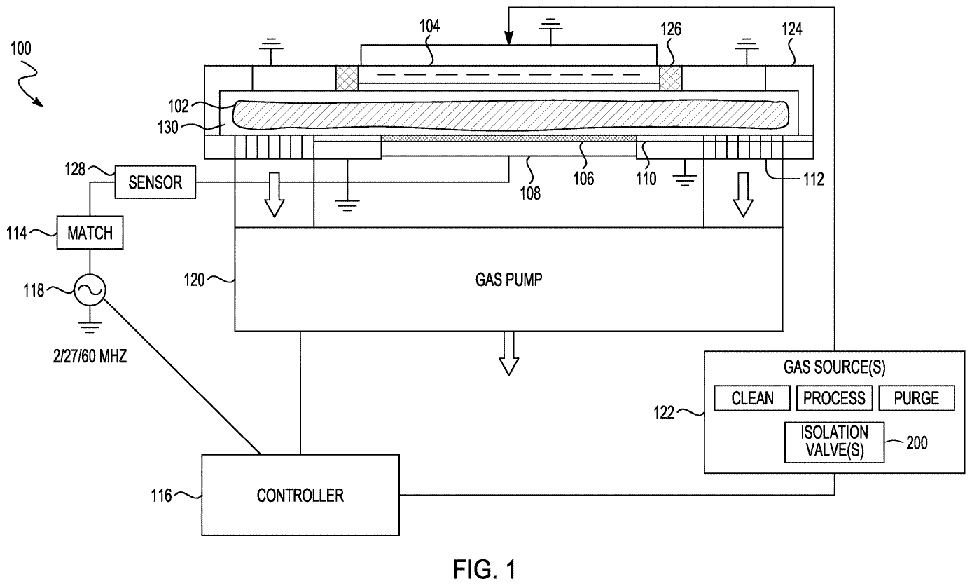

As used herein, the terms “wafer” and “substrate” are used interchangeably. A wafer or substrate indicates a support material upon which, or within which, elements of a semiconductor device are fabricated or attached. A substrate (e.g., substrate 106 in FIG. 1) may include, for example, wafers (e.g., having a diameter of 100 mm, 150 mm, 200 mm, 300 mm, 450 mm, or larger) composed of, for example, elemental-semiconductor materials (e.g., silicon (Si) or germanium (Ge)) or compound-semiconductor materials (e.g., silicon germanium (SiGe) or gallium arsenide (GaAs)). Additionally, other substrates include, for example, dielectric materials such as quartz or sapphire (onto which semiconductor materials may be applied). Example substrates include blanket substrates and patterned substrates. A blanket substrate is a substrate that comprises a low-surface (or planar) top surface. A patterned substrate is a substrate that comprises a high-surface (or structured) top surface. A structured top surface of a substrate may include different high-surface-area structures such as 3D NAND memory holes or other structures.

A general description of a process chamber using the disclosed methods is provided with reference to FIG. 1. FIG. 1 illustrates a process chamber 100 (e.g., an etching or deposition chamber) for manufacturing substrates, according to one embodiment. In some examples, the process chamber 100 may also be referred to as a vacuum chamber. Exciting an electric field between two electrodes is one of the methods to obtain radio frequency (RF) gas discharge in a process chamber. When an oscillating voltage is applied between the electrodes, the discharge obtained is referred to as a CCP discharge.

A plasma 102 may be created within a processing zone 130 of the process chamber 100, utilizing one or more process gases to obtain a wide variety of chemically reactive by-products created by the dissociation of the various molecules caused by electron-neutral collisions. The chemical aspect of etching involves the reaction of the neutral gas molecules and their dissociated by-products with the molecules of the to-be-etched surface and producing volatile molecules, which may be pumped away. When a plasma is created, the positive ions are accelerated from the plasma across a space-charge sheath separating the plasma from chamber walls to strike the substrate surface with enough energy to remove material from the substrate surface. The process of using highly energetic and chemically reactive ions to selectively and anisotropically remove materials from a substrate surface is called Reactive Ion Etch (RIE). In some examples, the process chamber 100 may be used in connection with PECVD or PEALD deposition processes.

A controller 116 manages the operation of the process chamber 100, such as during processing, clean and purge cycles, and by controlling the different elements in the process chamber 100, such as RF generator 118, gas source(s) 122, and gas pump 120. The gas source(s) 122 may include a cleaning gas source and a purge gas source. Other gas sources are possible. In one embodiment, fluorocarbon gases, such as CF₄ and C₄F₈, are used in a dielectric etch process for their anisotropic and selective etching capabilities; but the principles described herein may be applied to other plasma-creating gases. The fluorocarbon gases are readily dissociated into chemically reactive by-products that include smaller molecular and atomic radicals. These chemically reactive by-products etch away the dielectric material.

The process chamber 100 illustrates a processing chamber with an upper (or top) electrode 104 and a lower (or bottom) electrode 108. An example process in which an isolation valve of the present disclosure may be used comprises a thermal ALD process which may, or may not, include an in-situ plasma. Other example processes may include techniques such as etching, physical vapor deposition (PVD), atomic layer deposition (ALD), chemical vapor deposition (CVD), plasma-enhanced chemical vapor deposition (PECVD), pulsed deposition layer (PDL), plasma-enhanced pulsed deposition layer (PEPDL), and resist removal. The upper electrode 104 may be grounded or coupled to an RF generator (not shown), and the lower electrode 108 is coupled to the RF generator 118 via a matching network 114. The RF generator 118 provides an RF signal between the upper electrode 104 and the lower electrode 108 to generate RF power in one or multiple (e.g., two or three) different RF frequencies. According to a desired configuration of the process chamber 100 for a particular operation, at least one of the multiple RF frequencies may be turned ON or OFF. In the embodiment shown in FIG. 1, the RF generator 118 is configured to provide at least three different frequencies, e.g., 400 kHz, 2 MHz, 27 MHz, and 60 MHz, but other frequencies are also possible.

The process chamber 100 comprises a gas showerhead on the upper electrode 104 to input process gas into the process chamber 100 provided by the gas source(s) 122, and a perforated confinement ring 112 that allows the gas to be pumped out of the process chamber 100 by gas pump 120. In some example embodiments, the gas pump 120 is a turbomolecular pump, but other types of gas pumps may be utilized.

When the substrate 106 is present in the process chamber 100, the silicon focus ring 110 is situated next to substrate 106 such that there is a uniform RF field at the bottom surface of the plasma 102 for uniform etching (or deposition) on the surface of the substrate 106. The embodiment of FIG. 1 shows a triode reactor configuration where the upper electrode 104 is surrounded by a ground electrode 124 (e.g., a symmetric RF ground electrode). Insulator 126 is a dielectric that isolates the ground electrode 124 from the upper electrode 104. Other implementations of the process chamber 100, comprising ICP-based implementations, are also possible without changing the scope of the disclosed embodiments.

Each frequency generated by the RF generator 118 may be selected for a specific purpose in the substrate manufacturing process. In the example of FIG. 1, with RF powers provided at 400 kHz, 2 MHz, 27 MHz, and 60 MHz, the 400 kHz or 2 MHz RF power provides ion energy control, and the 27 MHz and 60 MHz powers provide control of the plasma density and the dissociation patterns of the chemistry. This configuration, where each RF power may be turned ON or OFF, enables certain processes that use ultra-low ion energy on the substrates, and certain processes (e.g., soft etch for low-k materials) where the ion energy has to be low (e.g., under 700 or 200 eV).

In another embodiment, a 60 MHz RF power is used on the upper electrode 104 to get ultra-low energies and very high density. This configuration allows chamber cleaning with high-density plasma when substrate 106 is not in the process chamber 100, while minimizing sputtering on the Electrostatic Chuck Surface (ESC). The ESC surface is exposed when substrate 106 is not present, and any ion energy on the surface should be avoided, which is why the bottom 2 MHz and 27 MHz power supplies may be off during cleaning.

In an example embodiment, the process chamber 100 further comprises a sensor 128 which may be placed between the matching network 114 of the RF generator 118 and the lower electrode 108. The sensor 128 may include a voltage-current (or V-I) sensor configured to generate a plurality of signals (e.g., sensed data) that are indicative of at least one signal characteristic of RF signals generated by the RF generator 118 at a corresponding plurality of time instances. For example, the V-I sensor may generate a plurality of signals that are indicative of one or more of the following signal characteristics of RF signals: voltage, current, phase, delivered power, and impedance. In some examples, the plurality of signals generated by the sensor 128 at the corresponding plurality of time instances may be stored (e.g., in on-chip memory of controller 116 or the sensor 128) and later retrieved (e.g., by the controller 116) for subsequent processing. In other aspects, the plurality of signals generated by the sensor 128, at the corresponding plurality of time instances, may be automatically communicated to the controller 116 as they are generated.

In some examples, the gas source(s) 122 are connected to one or more gas line supply arrangements disposed upstream of the gas showerhead on the upper electrode 104. The gas supply line arrangements may include one or more inlet manifolds (not visible in FIG. 1) connected to the process chamber 100. The gas source(s) 122 may include a process gas source, a cleaning gas source, and a purge gas source, each controlled by one or more isolation valves 200. In some examples, the gas line supply arrangements are connected to these gas sources 122 and are used for cleaning and purge cycles of the process chamber 100 between or after substrate processing cycles. Other sources of gas and arrangements of isolation valves, gas manifolds, and gas control componentry are possible.

In some applications, a clean gas isolation valve 200 is used to isolate downstream process gases in a mixing gas injector block from upstream clean gas in a manifold. Application requirements may include an ability to operate at high temperature (for example, 200° C.), a resistance to chlorine-containing deposition chemistry, a resistance to radical fluorine plasma/gas (such as a cleaning gas), an ability to operate dynamically (as opposed, for example, to a one-time use static seal), and allow for frequent use (for example, 1 to 2 times a day in a production environment). This combination of requirements, particularly the high temperature ability, the dynamic nature, and chemical resistance can make the valve application particularly challenging. Conventional isolation valves use an O-ring seal that that interfaces with an opposing sealing surface, for example a process gas injector block. The O-ring seal moves in a linear motion to open and close the isolation valve and dynamically seal against the opposing surface. This traditional solution is ubiquitous in valve applications but frequently fails, sometimes only lasting one or two cycles of operation.

Current technology is susceptible to several failure mechanisms, such as O-ring temperature deterioration. As O-ring polymer cross-links relax, filler materials can be released causing the mechanical properties of the O-ring to change unfavorably. O-ring plasma deterioration (both chemical and physical) can occur even in the best performing O-rings designed for plasma applications and will be etched to 0.2-1% material loss at best, depending on conditions. In some instances, an isolation valve will be stuck closed. Here, the O-ring sticks between interfacing materials after exposure to temperature and chemistry causing a separation force that is too high for the valve actuator to overcome. Moreover, when stuck, an isolation valve poppet (or closure) can break free from the valve actuator causing further damage to valve mounting features and the actuator. In other problems, the isolation valve body may overheat due to plasma recombination (exothermic) on the valve surfaces. In some instances, an isolation valve can heat up above a theoretical maximum operating temperature, causing degradation of the O-rings and other isolation valve components. O-ring material costs are high and high purity sealing ceramic surfaces used in conventional isolation valves can be expensive. A consequential problem caused by conventional O-ring degradation can include a lack of cleanliness and contamination downstream at a processed wafer. Chemical reactions, unwanted by-products, and material loss on the O-ring can enter process gas streams and cause defects on a processed wafer.

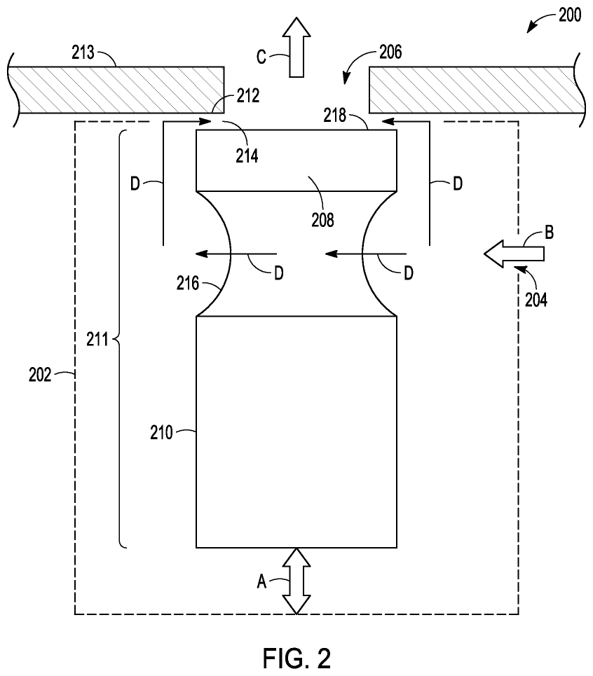

Present examples disclosed herein avoid the use of an O-ring. With reference to FIG. 2, an isolation valve 200 comprises a valve body 202 shown schematically in dotted outline. The body comprises an inlet shown generally at 204, and at outlet shown generally at 206. Other arrangements of inlet and outlet are possible. The isolation valve 200 comprises a poppet 208 and a poppet valve housing 210. The poppet valve housing 210 supports the poppet 208 inside the valve body 202. The poppet valve housing 210 and the poppet 208 together define a poppet valve assembly 211. The poppet valve assembly 211 can reciprocate axially (in the direction of arrow A) inside the valve body 202 to open and close the inlet 204 and/or the outlet 206 of the isolation valve 200. In some examples, the poppet valve housing 210 and the poppet 208 can be moved under action of a valve actuator (not shown) controlled by the controller 116 of FIG. 1. In some examples, the valve actuator is configured to exert a spring force sufficient to seal the poppet 208 when held against an opposing surface 212 in a closed position of the isolation valve 200. In some examples, when the actuator (e.g., comprising a spring) is in a free state the poppet 208 protrudes from the valve body 202 a short distance in the range of 1.0-1.5 mm which, when the spring is compressed, provides adequate clamping force to seal the poppet against the opposing surface 212 in use.

In some examples, the poppet valve assembly 211 is or comprises a unitary structure with the poppet 208 integrally formed with the poppet valve housing 210.

In some examples, in order to close the isolation valve 200, the poppet 208 can be moved to seal against an opposing surface 212 to block the passage of gas. The opposing surface 212 may be defined by an external component 213 to which the isolation valve 200 is fitted (for example, as shown), or provided inside the valve body 202. Other arrangements are possible. The poppet 208 seals against the opposing surface 212 without an O-ring seal. When the poppet 208 is moved away from the opposing surface 212, the isolation valve 200 is opened. When the poppet 208 is moved in the other direction and engages with the opposing surface 212, the isolation valve 200 is closed.

When the isolation valve 200 is open, gas can enter the isolation valve 200 through the inlet 204 as shown by the arrow B, and exit the valve 200 through the outlet 206 as shown by the arrow C. Example gas flow inside the valve body 202 is shown by the arrows marked D. As shown, gas can pass through the inlet 204 and subsequently through a gap 214 between the poppet 208 and the opposing surface 212. In some examples, an indented or curved passage 216 is provided in the poppet valve housing 210 to facilitate an unrestricted flow of gas inside the valve body 202 and seek to prevent overheating of the isolation valve 200.

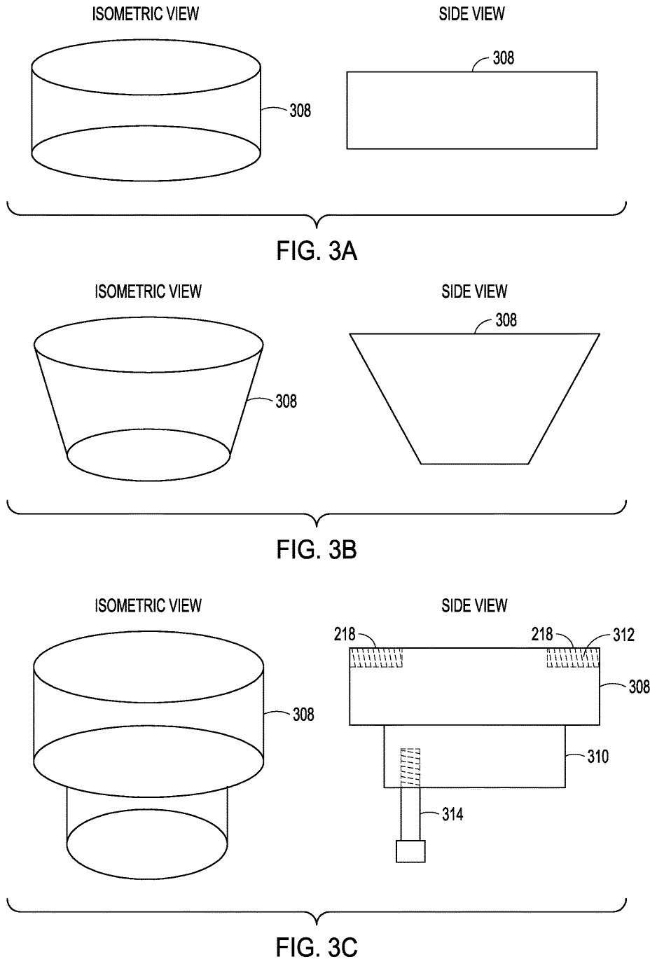

In some examples, the poppet 208 comprises polytetrafluoroethylene (PTFE) material. In some examples, the poppet 208 is entirely constituted by, or is formed from, a solid block of PTFE material. In some examples, only a portion or sub-section of the poppet 208 comprises PTFE material. In some examples, only a sealing surface 218 of the poppet, disposed opposite the opposing surface 212, is defined by or comprises PTFE material. In some examples, the sealing surface 218 is defined by the portion or sub-section of the poppet 208, for example as shown at 312 in FIG. 3C. Other configurations of portions or sub-sections of the poppet 208 and the poppet 308 are possible. The PTFE material is used as a sealing material for the poppet 208 of isolation valve 200 and can engage fully with an opposing surface without need of an O-ring to seal the inlet 204 and close the valve 200.

The use of a poppet 208 comprising PTFE as a sealing material can address many of the failure mechanisms discussed above. Primarily, the use of an O-ring and its attendant complications can be avoided. A poppet 208 comprising PTFE strongly resists temperature deterioration. The PTFE material does not include cross-links or filler materials and is generally safe for operation up to 260° C. Further, the PTFE material only comprises carbon-fluorine (C-F) bonds and is completely inert to radical fluorine and halide-containing chemistries such as HCl and chlorine trifluoride (CIF3). In testing, some examples of a poppet 208 comprising PTFE were found to exhibit less than 0.01% by weight loss of PTFE material after long-term exposure (72 hours) to radical fluorine at 200 C. The conventional issue of stuck isolation valves is reduced, if not solved completely. PTFE has excellent low friction characteristics and requires near zero force to separate from an opposing surface when opening. The low friction reduces applied stresses and the consequent issue of valve poppet separation is addressed. Further, PTFE is thermally insulative and has a low (nearly zero) recombination rate with fluorine plasma. These characteristics help to reduce the issue of overheating valves. PTFE material is significantly less expensive than ceramic alternatives and valve construction and assembly costs can be significantly reduced. Wafer processing cleanliness is significantly improved as the PTFE material is very pure and, as it does not react with gasses and other plasma chemistry, there is very little, if any, material degradation to cause wafer contamination downstream of the isolation valve 200.

Examples isolation valves of the present disclosure have been tested in use and observed to isolate gasses effectively, without use of an O-ring, and without defect for many hundreds of cycles of operation and/or for periods of operation. Example periods of substantially defect-free use range between approximately 6-8 months, or 10-12 months if used within ideal operating conditions. These periods may include in some examples approximately 200-700 open/close cycles as compared to some conventional isolation valves failing in approximately 1-2 cycles.

FIGS. 3A-3C include side pictorial views of different configurations of poppet, according to example embodiments. With reference to FIG. 3A, a poppet 308 may include a cylindrical (puck shaped) body configuration, for example as shown. With reference to FIG. 3B, a poppet 308 may include a frustoconical or tapered body configuration, for example as shown. With reference again to FIG. 3C, in some examples, a poppet 308 may include a recess or step 310 configured to fit with a matching formation inside the poppet valve housing 210. Other inter-engageable poppet configurations and support arrangements are possible. For example, the poppet 208 or the poppet 308 may be secured to the poppet valve housing 210 by means of one or more axial screws, or otherwise secured to the poppet valve housing 210, for example by adhesive. The one or more axial screws 314 may be positioned, for example at an off-center axial location as shown, across an interface between the poppet 208/308 and the poppet valve housing 210 to prevent relative rotational movement there between. In some examples, the one or more axial screws is engaged in a threaded insert (not shown) in the PTFE material. In some examples, the PTFE material operates to “self-seal” the isolation valve 200 in the sense not only that it seals against the opposing surface 212 to close the inlet 204 when the valve is closed, but also operates to seal the surfaces of the poppet 208/308 adjacent the one or more axial screws 314 to prevent the passage of gas across the interface between the poppet 208/308 and the poppet valve housing 210.

In some examples, the poppet 208/308 is retrofittable into existing isolations valve(s) 200 operating in the field. In some examples, a lay pattern and low surface roughness is provided on the sealing surface 312 of the poppet 208/308. Some examples may include a high polish on the sealing surface 312 of the poppet 208/308. Some examples include a surface roughness in the order of 8-16 microinches Ra (0.2-0.4 microns). In some examples, the sealing surface 312 and/or the lay pattern on the sealing surface extends over a full surface of the top of the poppet 208/308 (in the views), or only a portion thereof. In some examples, the top of the poppet 208/308 (in the views) and/or the sealing surface 312 is devoid of an O-ring seating channel (or groove).

In some examples, the poppet 208/308, and/or the poppet valve housing 210, and/or the poppet valve assembly 211 is cylindrical and has a circular cross section. In some examples, a cylindrical poppet 208/308 comprises a circular sealing surface sized to seal adequately with an opposing surface 212. In some examples, the poppet 208/308, and/or the poppet valve housing 210, and/or the poppet valve assembly 211 is not circular cylindrical and may include oval or square cross-sections, for example. In some examples, a cylindrical poppet 208/308 comprises a non-circular sealing surface sized to seal adequately with an opposing surface 212. The opposing surface 212 may be circular or non-circular, in some examples. As mentioned above, in some examples, the poppet valve assembly 211 is or comprises a unitary structure with the poppet 208 integrally formed with the poppet valve housing 210. In some examples comprising a poppet 208/308 formed wholly or in part of PTFE material, the poppet valve assembly is or comprises a multi-part structure in which the PTFE material is replaceable. In some examples, the multi-part structure mitigates the effect of any dimension creep of the PTFE material by having less of the PTFE material as a constituent part.

Some examples include elements as follows:

Example 1 includes an isolation valve comprising: a valve body; a valve actuator; and a poppet comprising a polytetrafluoroethylene (PTFE) material, the poppet movable in the valve body by the valve actuator to hold the PTFE material in sealing engagement with an opposing surface without intervention of an O-ring.

Example 2 includes the features of Example 1, wherein the poppet is a unitary structure comprised entirely of or constructed entirely from the PTFE material.

Example 3 includes the features of either one of Example 1-2, wherein the poppet is devoid of an O-ring seating channel.

Example 4 includes the features of any one of Examples 1-3, wherein the poppet comprises a recess or step.

Example 5 includes the features of any one of Examples 1-4, further comprising a poppet valve assembly comprising a poppet valve housing and a section defined by the poppet.

Example 6 includes the features of any one of Examples 1-5, wherein the poppet is formed separately to the poppet valve housing.

Example 7 includes the features of any one of Examples 1-6, wherein the poppet valve assembly is a unitary structure with the section defined by the poppet formed integrally with the poppet valve housing.

Example 8 includes the features of any one of Examples 1-7, wherein the poppet comprises a recess or step configured to fit with a matching formation inside the poppet valve housing.

Example 9 includes an O-ring-less poppet for an isolation valve, the isolation valve comprising a valve body and a valve actuator, the O-ring-less poppet comprising: a section of (PTFE) material defining a sealing surface, the sealing surface devoid of an O-ring seating channel, the poppet movable in the valve body by the valve actuator to hold the sealing surface defined by the PTFE material in sealing engagement with an opposing surface without intervention of an O-ring when the isolation valve is closed.

Example 10 includes the features of Example 9, wherein the O-ring-less poppet comprises a recess or step.

Example 11 includes the features of either one of Examples 9-10, wherein the O-ring-less poppet is a unitary structure comprised entirely of or constructed entirely from the PTFE material.

Example 12 includes the features of any one of Examples 9-11, wherein the isolation valve comprises a poppet valve assembly comprising a poppet valve housing and the O-ring-less poppet.

Example 13 includes the features of any one of Examples 9-12, wherein the O-ring-less poppet is formed separately to the poppet valve housing.

Example 14 includes the features of any one of Examples 9-13, wherein the poppet valve assembly is a unitary structure with the O-ring-less poppet formed integrally with the poppet valve housing.

Example 15 includes the features of any one of Examples 90-14, wherein the O-ring-less poppet comprises a recess or step configured to fit with a matching formation inside the poppet valve housing.

Example 16 includes a poppet valve assembly for an isolation valve comprising a valve body and a valve actuator, the poppet valve assembly comprising: a poppet valve housing; and a poppet, the poppet comprising a section of (PTFE) material defining a sealing surface, the sealing surface devoid of an O-ring seating channel, the poppet movable in the valve body by the valve actuator to hold the sealing surface defined by the PTFE material in sealing engagement with an opposing surface without intervention of an O-ring when the isolation valve is closed.

Example 17 includes the features of Example 16, wherein the poppet comprises a recess or step.

Example 18 includes the features of either one of Examples 15-16, wherein the recess or step is configured to fit with a matching formation inside the poppet valve housing.

Example 19 includes the features of any one of Examples 16-18, wherein the poppet is a unitary structure comprised entirely of or constructed entirely from the PTFE material.

Example 20 includes the features of any one of Examples 16-19, wherein the poppet is formed separately to the poppet valve housing.

Example 21 includes the features of any one of Examples 16-20, wherein the poppet valve assembly is a unitary structure with the poppet formed integrally with the poppet valve housing.

Example 22 includes a method of operating an isolation valve, the method comprising: installing, without intervention of a poppet O-ring, the isolation valve in a gas supply line of a process chamber, the isolation valve comprising: a valve body; a valve actuator; and a poppet comprising a polytetrafluoroethylene (PTFE) material, the poppet movable in the valve body by the valve actuator to hold the PTFE material in sealing engagement with an opposing surface without intervention of an O-ring; and supplying a gas through the isolation valve; and processing a substrate in the process chamber.

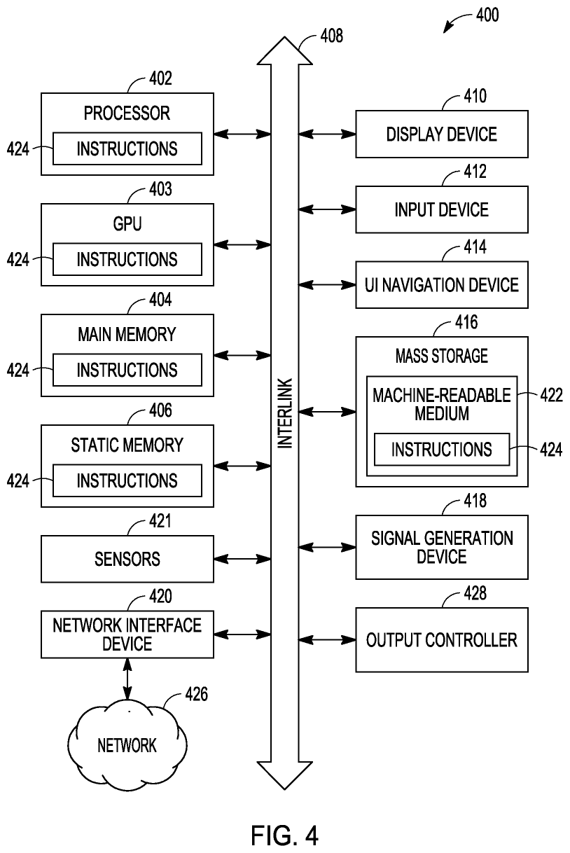

FIG. 4 is a block diagram illustrating an example of a machine 400 (such as the controller 116 of FIG. 1) upon or by which one or more example process embodiments described herein may be implemented or controlled. In alternative embodiments, the machine 400 may operate as a standalone device or may be connected (e.g., networked) to other machines. In a networked deployment, the machine 400 may operate in the capacity of a server machine, a client machine, or both in server-client network environments. In an example, the machine 400 may act as a peer machine in a peer-to-peer (P2P) (or other distributed) network environment. Further, while only a single machine 400 is illustrated, the term “machine” shall also be taken to include any collection of machines that individually or jointly execute a set (or multiple sets) of instructions to perform any one or more of the methodologies discussed herein, such as via cloud computing, software as a service (Saas), or other computer cluster configurations.

Examples, as described herein, may include, or may operate by, logic, several components, or mechanisms. Circuitry is a collection of circuits implemented in tangible entities that include hardware (e.g., simple circuits, gates, logic). Circuitry membership may be flexible over time and underlying hardware variability. Circuitries include members that may, alone or in combination, perform specified operations when in use. In one example, the hardware of the circuitry may be immutably designed to carry out a specific operation (e.g., hardwired). In another example, the hardware of the circuitry may include variably connected physical components, (e.g., execution units, transistors, simple circuits) comprising a computer-readable medium physically modified (e.g., magnetically and electrically by the moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In some examples, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 400 may include a hardware processor 402 (e.g., a central processing unit (CPU), a hardware processor core, or any combination thereof), a graphics processing unit (GPU) 403, a main memory 404, and a static memory 406; some or all of which may communicate with each other via an interlink (e.g., bus) 408. The machine 400 may further include a display device 410, an alphanumeric input device 412 (e.g., a keyboard), and a user interface (UI) navigation device 414 (e.g., a mouse). In an example, the display device 410, alphanumeric input device 412, and UI navigation device 414 may be a touch screen display. The machine 400 may additionally include a mass storage device (e.g., drive unit) 416, a signal generation device 418 (e.g., a speaker), a network interface device 420, and one or more sensors 421, such as a Global Positioning System (GPS) sensor, compass, accelerometer, or another sensor. The machine 400 may include an output controller 428, such as a serial (e.g., Universal Serial Bus (USB)), parallel, or other wired or wireless (e.g., Infrared (IR), Near Field Communication (NFC)) connection to communicate with or control one or more peripheral devices (e.g., a printer, card reader).

In an example embodiment, the hardware processor 402 may perform the functionalities of the controller 116 discussed herein.

The mass storage device 416 may include a machine-readable medium 422 on which is stored one or more sets of data structures or instructions 424 (e.g., software) embodying or utilized by any one or more of the techniques or functions described herein. The instructions 424 may also reside, completely or at least partially, within the main memory 404, within the static memory 406, within the hardware processor 402, or within the GPU 403 during execution thereof by the machine 400. In an example, one or any combination of the hardware processor 402, the GPU 403, the main memory 404, the static memory 406, or the mass storage device 416 may constitute machine-readable media.

While the machine-readable medium 422 is illustrated as a single medium, the term “machine-readable medium” may include a single medium or multiple media, (e.g., a centralized or distributed database, and/or associated caches and servers) configured to store the one or more instructions 424.

The term “machine-readable medium” may include any medium that is capable of storing, encoding, or carrying instructions 424 for execution by the machine 400 and that cause the machine 400 to perform any one or more of the techniques of the present disclosure, or that is capable of storing, encoding, or carrying data structures used by or associated with such instructions 424. Non-limiting machine-readable medium examples may include solid-state memories and optical and magnetic media. In an example, a massed machine-readable medium comprises a machine-readable medium 422 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 424 may further be transmitted or received over a communications network 426 using a transmission medium via the network interface device 420.

Implementation of the preceding techniques may be accomplished through any number of specifications, configurations, or example deployments of hardware and software. It should be understood that the functional units or capabilities described in this specification may have been referred to or labeled as components or modules in order to emphasize their implementation independence more particularly. Such components may be embodied by any number of software or hardware forms. For example, a component or module may be implemented as a hardware circuit comprising custom, very-large-scale integration (VLSI) circuits, or gate arrays, off-the-shelf semiconductors such as logic chips, transistors, or other discrete components. A component or module may also be implemented in programmable hardware devices such as field-programmable gate arrays, programmable array logic, programmable logic devices, or the like. Components or modules may also be implemented in software for execution by various types of processors. An identified component or module of executable code may, for instance, comprise one or more physical or logical blocks of computer instructions, which may, for instance, be organized as an object, procedure, or function. Nevertheless, the executables of an identified component or module need not be physically located together but may comprise disparate instructions stored in different locations which, when joined logically together, comprise the component or module and achieve the stated purpose for the component or module.

Indeed, a component or module of executable code may be a single instruction, or many instructions, and may even be distributed over several different code segments, among different programs, and across several memory devices or processing systems. In particular, some aspects of the described process (such as code rewriting and code analysis) may take place on a different processing system (e.g., in a computer in a data center) than that in which the code is deployed (e.g., in a computer embedded in a sensor or robot). Similarly, operational data may be identified and illustrated herein within components or modules and may be embodied in any suitable form and organized within any suitable type of data structure. The operational data may be collected as a single data set or may be distributed over different locations comprising over different storage devices, and may exist, at least partially, merely as electronic signals on a system or network. The components or modules may be passive or active, comprising agents operable to perform desired functions.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components for example configurations may be implemented as a combined structure or component. Similarly, structures and functionality presented as a single component may be implemented as separate components. These and other variations, modifications, additions, and improvements fall within the scope of the subject matter herein.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

The claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within the scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

What is claimed is:

1. An isolation valve comprising:
a valve body;
a valve actuator; and
a poppet comprising a polytetrafluoroethylene (PTFE) material, the poppet movable in the valve body by the valve actuator to hold the PTFE material in sealing engagement with an opposing surface without intervention of an O-ring.

2. The isolation valve of claim 1, wherein the poppet is a unitary structure comprised entirely of or constructed entirely from the PTFE material.

3. The isolation valve of claim 2, wherein the poppet is devoid of an O-ring seating channel.

4. The isolation valve of claim 1, wherein the poppet comprises a recess or step.

5. The isolation valve of claim 1, further comprising a poppet valve assembly comprising a poppet valve housing and a section defined by the poppet.

6. The isolation valve of claim 5, wherein the poppet is formed separately to the poppet valve housing.

7. The isolation valve of claim 5, wherein the poppet valve assembly is a unitary structure with the section defined by the poppet formed integrally with the poppet valve housing.

8. The isolation valve of claim 5, wherein the poppet comprises a recess or step configured to fit with a matching formation inside the poppet valve housing.

9. An O-ring-less poppet for an isolation valve, the isolation valve comprising a valve body and a valve actuator, the O-ring-less poppet comprising:
a section of (PTFE) material defining a sealing surface, the sealing surface devoid of an O-ring seating channel, the poppet movable in the valve body by the valve actuator to hold the sealing surface defined by the PTFE material in sealing engagement with an opposing surface without intervention of an O-ring when the isolation valve is closed.

10. The O-ring-less poppet of claim 9, wherein the O-ring-less poppet comprises a recess or step.

11. The O-ring-less poppet of claim 9, wherein the O-ring-less poppet is a unitary structure comprised entirely of or constructed entirely from the PTFE material.

12. The O-ring-less poppet of claim 9, wherein the isolation valve comprises a poppet valve assembly comprising a poppet valve housing and the O-ring-less poppet.

13. The O-ring-less poppet of claim 12, wherein the O-ring-less poppet is formed separately to the poppet valve housing.

14. The O-ring-less poppet of claim 12, wherein the poppet valve assembly is a unitary structure with the O-ring-less poppet formed integrally with the poppet valve housing.

15. The O-ring-less poppet of claim 12, wherein the O-ring-less poppet comprises a recess or step configured to fit with a matching formation inside the poppet valve housing.

16. A poppet valve assembly for an isolation valve comprising a valve body and a valve actuator, the poppet valve assembly comprising:
a poppet valve housing; and
a poppet, the poppet comprising a section of (PTFE) material defining a sealing surface, the sealing surface devoid of an O-ring seating channel, the poppet movable in the valve body by the valve actuator to hold the sealing surface defined by the PTFE material in sealing engagement with an opposing surface without intervention of an O-ring when the isolation valve is closed.

17. The poppet valve assembly of claim 16, wherein the poppet comprises a recess or step.

18. The poppet valve assembly of claim 17, wherein the recess or step is configured to fit with a matching formation inside the poppet valve housing.

19. The poppet valve assembly of claim 16, wherein the poppet is a unitary structure comprised entirely of or constructed entirely from the PTFE material.

20. The poppet valve assembly of claim 16, wherein the poppet is formed separately to the poppet valve housing.

21. The poppet valve assembly of claim 16, wherein the poppet valve assembly is a unitary structure with the poppet formed integrally with the poppet valve housing.

22. A method of operating an isolation valve, the method comprising:
installing, without intervention of a poppet O-ring, the isolation valve in a gas supply line of a process chamber, the isolation valve comprising:
a valve body;
a valve actuator; and
a poppet comprising a polytetrafluoroethylene (PTFE) material, the poppet movable in the valve body by the valve actuator to hold the PTFE material in sealing engagement with an opposing surface without intervention of an O-ring; and
supplying a gas through the isolation valve; and
processing a substrate in the process chamber.
